(19) United States
(12) Patent Application Publication
(10) Pub. No.: US 2020/0303198 A1
(43) Pub. Date: Sep. 24, 2020

(54) POLISHING COMPOSITION AND POLISHING METHOD

(71) Applicant: FUJIMI INCORPORATED, Aichi (JP)

(72) Inventors: YUSUKE KADOHASHI, Aichi (JP); YOSHIHIRO IZAWA, Aichi (JP); AKIKO SOUMIYA, Aichi (JP)

(73) Assignee: FUJIMI INCORPORATED, Aichi (JP)

(21) Appl. No.: 16/813,260

(22) Filed: Mar. 9, 2020

(30) Foreign Application Priority Data
Mar. 22, 2019 (JP) 2019-054908
Sep. 4, 2019 (JP) 2019-161443

(51) Int. Cl. H01L 21/302; C09G 1/02

(52) U.S. Cl. CPC H01L 21/302; C09K 3/1463; C09G 1/02

(57) ABSTRACT

A polishing composition according to the present invention contains: silica particles; a polishing speed adjusting agent for an object to be polished containing a silicon material having silicon-silicon bonding; and a biocide. The biocide includes a carbon atom, a hydrogen atom, and an oxygen atom.

### CROSS-REFERENCE TO RELATED APPLICATION

This application claims priority to Japanese Patent Application No. 2019-054908, filed on Mar. 22, 2019, and Japanese Patent Application No. 2019-161443, filed on Sep. 4, 2019, the contents of all of which are incorporated herein in their entirety.

### BACKGROUND

### 1. Technical Field

The present invention relates to a polishing composition and a polishing method.

### 2. Description of Related Arts

In recent years, a so-called chemical mechanical polishing (CMP) technique for polishing and flattening a semiconductor substrate in producing a device is used in accordance with multilayer wiring on a surface of a semiconductor substrate. CMP is a method for flattening the surface of an object to be polished (workpiece), such as a semiconductor substrate, by using a polishing composition (slurry) containing abrasive grains such as silica, alumina, or ceria, an anti-corrosion agent, a surfactant, and the like. The object to be polished (workpiece) is, for example, silicon, polysilicon, silicon oxide film (silicon oxide), silicon nitride, or a wiring, plug, or the like made of metal or the like.

In such a polishing composition, the proliferation of viable cells may progress to degrade storage stability. To ensure the storage stability, for example, Japanese Patent Application Laid-Open (JP-A) No. 2007-88379 (corresponding to U.S. Patent Application Publication No. 2007/069176) proposes a polishing composition containing (a) colloidal silica having the surface partially coated with aluminum atoms and (b) at least one compound having an isothiazolin-3-one skeleton.

### SUMMARY

However, it has been found that application of the technique described in JP-A No. 2007-88379 (corresponding to U.S. Patent Application Publication No. 2007/069176) to an object to be polished containing a silicon material having silicon-silicon bonding, such as polysilicon, causes a problem in which the polishing performance on an object to be polished, which the polishing composition originally has, changes.

Accordingly, an object of the present invention is to provide a means that has high storage stability with proliferation of viable cells suppressed and that can maintain the original polishing performance on an object to be polished containing a silicon material having silicon-silicon bonding.

To solve the above problem, the inventors of the present invention have conducted intensive studies. As a result, it has been found that the above problem is solved by a polishing composition containing silica particles, a polishing speed adjusting agent for an object to be polished containing a silicon material having silicon-silicon bonding, and a biocide, wherein the biocide includes a carbon atom, a hydrogen atom, and an oxygen atom. The present invention is completed accordingly.

### DETAILED DESCRIPTION

The embodiments of the present invention will be described below. However, the present invention is not limited to the following embodiments. In this specification, unless otherwise specified, operations and measurement of physical properties or the like are carried out under the conditions of room temperature (20° C. or higher and 25° C. or lower)/relative humidity of 40% RH or higher and 50% RH or lower.

A polishing composition according to an embodiment of the present invention contains silica particles, a polishing speed adjusting agent for an object to be polished containing a silicon material having silicon-silicon bonding, and a biocide. The biocide includes a carbon atom, a hydrogen atom, and an oxygen atom.

Having such a feature provides a polishing composition that has high storage stability with proliferation of viable cells suppressed and that can maintain the original polishing performance on an object to be polished containing a silicon material having silicon-silicon bonding.

### <Object to be Polished>

The object to be polished according to the present invention contains a silicon material having silicon-silicon bonding. Examples of the silicon material having silicon-silicon bonding include polysilicon (Poly-Si), amorphous silicon, single crystal silicon, n-type doped single crystal silicon, p-type doped single crystal silicon, Si-based alloys, such as SiGe, and the like. Among these, polysilicon is preferred.

The object to be polished may further contain materials other than the silicon material having silicon-silicon bonding. Examples of other materials include silicon oxide, silicon nitride, silicon carbonitride (SiCN), metals, and the like.

### [Silica Particles]

A polishing composition according to an embodiment of the present invention contains silica particles as abrasive grains. Abrasive grains have an effect of mechanically polishing an object to be polished.

Examples of the type of silica particles include, but are not limited to, fumed silica, colloidal silica, and the like. Colloidal silica is preferred. Examples of the method for manufacturing colloidal silica include a sodium silicate method and a sol-gel method. Colloidal silica manufactured by either manufacturing method is suitably used as the silica particles according to the present invention. However, colloidal silica manufactured by a sol-gel method is preferred in order to reduce metal impurities. Colloidal silica manufactured by a sol-gel method is preferred since such colloidal silica contains small amounts of metal impurities having a property of being diffused in semiconductors and corrosive ions, such as a chloride ion. The manufacture of colloidal silica by a sol-gel method can be carried out by using a process known in the related art. Specifically, colloidal silica can be produced by performing a hydrolysis-condensation reaction using a hydrolyzable silicon compound (e.g., alkoxysilane or a derivative thereof) as a raw material.

The silica particles may have a cationic group. In other words, the silica particles may be a cationically modified silica particles or may be cationically modified colloidal silica. Examples of suitable colloidal silica (cationically modified colloidal silica) having a cationic group include colloidal silica having an amino group immobilized on the surface.

Examples of the method for manufacturing such colloidal silica having a cationic group include a method involving immobilizing, on the surface of silica particles, a silane coupling agent having an amino group, such as aminoethyltrimethoxysilane, aminopropyltrimethoxysilane, aminoethyltriethoxysilane, aminopropyltriethoxysilane, aminopropyldimethylethoxysilane, aminopropylmethyldiethoxysilane, or aminobutyltriethoxysilane, as described in JP-A No. 2005-162533. Colloidal silica (amino group-modified colloidal silica) having an amino group immobilized on the surface can be produced accordingly.

Colloidal silica may have an anionic group. In other words, the silica particles may be an anionically modified silica particles or may be anionically modified colloidal silica. Examples of suitable colloidal silica (anionically modified colloidal silica) having an anionic group include colloidal silica having an anionic group, such as carboxylic acid group, sulfonic acid group, phosphonic acid group, or aluminic acid group, immobilized on the surface. Examples of the method for manufacturing such colloidal silica having an anionic group include, but are not limited to, a method involving causing reaction between colloidal silica and a silane coupling agent having an anionic group in the terminal.

In a specific example, the immobilization of sulfonic acid groups to colloidal silica can be carried out by, for example, the method described in “Sulfonic acid-functionalized silica through of thiol groups”, Chem. Commun. 246-247 (2003). Specifically, a silane coupling agent having a thiol group, such as 3-mercaptopropyltrimethoxysilane, is coupled to colloidal silica, and the thiol group is then oxidized with hydrogen peroxide to produce colloidal silica (sulfonic acid-modified colloidal silica) having sulfonic acid groups immobilized on the surface.

The immobilization of carboxylic acid groups to colloidal silica can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3,228-229 (2000). Specifically, a silane coupling agent containing photolabile 2-nitrobenzyl ester is coupled to colloidal silica, and the resulting colloidal silica is then subjected to photoirradiation to produce colloidal silica (carboxylic acid-modified colloidal silica) having carboxylic acid groups immobilized on the surface.

Among the foregoing, the silica particles are preferably cationically modified silica particles in order to efficiently obtain desired advantageous effects of the present invention.

The shape of the silica particles is not limited and may be spherical or may be non-spherical. Specific examples of non-spherical shapes include, but are not limited to, various shapes, such as polygonal prisms, such as triangular prisms and quadrangular prisms, a cylindrical shape, a barrel shape in which the central part of a cylinder swells more than the ends, a doughnut shape in which the central part of a disk is open, a plate shape, a so-called cocoon shape which is narrow in the central part, a so-called associated spherical shape in which multiple particles is integrated, a so-called pointed candy ball (Japanese sugar plum candy Konpeito) shape having multiple projections on the surface, and a rugby ball shape.

The size of the silica particles is not limited. However, the lower limit of the average primary particle size of the silica particles is preferably 5 nm or more, more preferably 7 nm or more, and still more preferably 10 nm or more. In the polishing composition according to the present invention, the upper limit of the average primary particle size of the silica particles is preferably 120 nm or less, more preferably 80 nm or less, and still more preferably 50 nm or less. With this range, it is possible to suppress defects such as scratches on the surface of an object to be polished after polishing using the polishing composition. In other words, the average primary particle size of the silica particles is preferably 5 nm or more and 120 nm or less, more preferably 7 nm or more and 80 nm or less, and still more preferably 10 nm or more and 50 nm or less. The average primary particle size of the silica particles can be calculated, for example, based on the specific surface area of the silica particles measured by a BET method.

The lower limit of the average secondary particle size of the silica particles is preferably 10 nm or more, more preferably 20 nm or more, and still more preferably 30 nm or more. The upper limit of the average secondary particle size of the silica particles is preferably 250 nm or less, more preferably 200 nm or less, and still more preferably 150 nm or less. With this range, it is possible to suppress defects such as scratches on the surface of an object to be polished after polishing using the polishing composition. In other words, the average secondary particle size of the silica particles is preferably 10 nm or more and 250 nm or less, more preferably 20 nm or more and 200 nm or less, and still more preferably 30 nm or more and 150 nm or less. The average secondary particle size of the silica particles can be measured by, for example, a dynamic light scattering method represented by a laser diffraction/scattering method.

The average association degree of the silica particles is preferably 5.0 or less, more preferably 3.0 or less, and still more preferably 2.5 or less. As the average association degree of the silica particles decreases, it is possible to further reduce generation of defects on the surface of an object to be polished. The average association degree of the silica particles is preferably 1.0 or more, and more preferably 1.2 or more. As the average association degree of the silica particles increases, there is an advantage in enhancing the polishing speed using the polishing composition. The average association degree of the silica particles is obtained by dividing the value of the average secondary particle size of the silica particles by the value of the average primary particle size.

The upper limit of the aspect ratio of the silica particles is not limited, but preferably less than 2.0, more preferably 1.8 or less, and still more preferably 1.5 or less. With this range, it is possible to further reduce defects on the surface of an object to be polished. The aspect ratio is an average of values obtained by dividing the length of a long side of the smallest rectangle circumscribed to an image of a silica particle taken with a scanning electron microscope by the length of a short side of the same rectangle, and can be determined by using common image analysis software. The lower limit of the aspect ratio of the silica particles is not limited but preferably 1.0 or more.

In the particle size distribution of the silica particles as determined by a laser diffraction/scattering method, the lower limit of D90/D10, which is the ratio of the particle diameter (D90) when the cumulative particle weight from the finer particle side reaches 90% of the total particle weight to the particle diameter (D10) when the cumulative particle weight reaches 10% of the total particle weight of all particles, is not limited but preferably 1.1 or more, more preferably 1.2 or more, and still more preferably 1.3 or more. In the particle size distribution of the silica particles in the polishing composition as determined by a laser diffraction/scattering method, the upper limit of the ratio D90/D10 of the particle diameter (D90) when the cumulative particle weight from the finer particle side reaches 90% of the total particle weight to the particle diameter (D10) when the cumulative particle weight reaches 10% of the total particle weight of all particles is not limited but preferably 2.04 or less. With this range, it is possible to further reduce defects on the surface of an object to be polished.

The size (e.g., average primary particle size, average secondary particle size, aspect ratio, D90/D10, and the like) of the silica particles can be appropriately controlled by, for example, selecting the method for manufacturing silica particles.

The lower limit of the amount (concentration) of the silica particles in the polishing composition according to the embodiment of the present invention is preferably 0.01 mass % or more, more preferably 0.05 mass % or more, and still more preferably 0.1 mass % or more. The upper limit of the amount of the silica particles in the polishing composition according to the embodiment of the present invention is preferably 20 mass % or less, more preferably 10 mass % or less, still more preferably 5 mass % or less, and yet still more preferably 3 mass % or less. When the amount of the silica particles is in this range, it is possible to further suppress surface defects on the surface of an object to be polished after polishing using the polishing composition. When the polishing composition contains two or more types of silica particles, the amount of the silica particles refers to the total amount of two or more types of silica particles.

The polishing composition according to the embodiment of the present invention may further contain other abrasive grains in addition to silica particles.

Examples of other abrasive grains include metal oxide particles, such as alumina particles, zirconia particles, and titania particles.

### [Polishing Speed Adjusting Agent]

The polishing composition according to the embodiment of the present invention contains a polishing speed adjusting agent having a function of adjusting the polishing speed for an object to be polished containing a silicon material having silicon-silicon bonding.

Examples of the polishing speed adjusting agent include polishing speed enhancers having a function of enhancing the polishing speed for an object to be polished and polishing speed inhibitors having a function of reducing the polishing speed for an object to be polished. Either polishing speed adjusting agent can be used in the polishing composition according to the embodiment of the present invention.

### <Polishing Speed Enhancer>

Examples of polishing speed enhancers include water-soluble polymers, such as polycarboxylic acids, polycarboxylic acid amides, polycarboxylic acid esters, polycarboxylic acid salts, polysulfonic acids, polyphosphonic acids, and vinyl polymers; amide compounds, imide compounds, and amine compounds.

More specifically, examples of polycarboxylic acids include polyaspartic acid, polyglutamic acid, polymalic acid, polyacrylic acid, polymethacrylic acid, polymaleic acid, polyitaconic acid, polyfumaric acid, poly(p-styrenecarboxylic acid), polyamic acid, and the like.

Examples of polycarboxylic acid amides include polyacrylamide, polymethacrylamide, aminopolyacrylamide, aminopolymethacrylamide, and the like.

Examples of polycarboxylic acid esters include polymethyl acrylate, polymethyl methacrylate, polyethyl acrylate, polyethyl methacrylate, and the like.

Examples of polycarboxylic acid salts include polyacrylic acid ammonium salt, polymethacrylic acid ammonium salt, polyacrylic acid sodium salt, polymethacrylic acid sodium salt, polyamic acid ammonium salt, polyamic acid sodium salt, and the like.

Examples of polysulfonic acids include polystyrene sulfonic acid, polyisoprene sulfonic acid, sulfonic acid (salt) group-containing polyvinyl alcohol (sulfonic acid-modified polyvinyl alcohol), sulfonic acid (salt) group-containing polyvinyl acetate (sulfonic acid-modified polyvinyl acetate), sulfonic acid (salt) group-containing polyester, (meth) acrylic group-containing monomer-sulfonic acid (salt) group-containing monomer copolymer, sulfonic acid (salt)-containing allyl polymer, and the like.

Examples of vinyl polymers include polyvinyl alcohol, polyvinylpyrrolidone, a copolymer thereof, and the like.

Examples of amide compounds include acetamide, malonamide, succinamide, maleamide, fumaramide, benzamide, naphthamide, phthalamide, isophthalamide, terephthalamide, nicotinamide, isonicotinamide, formamide, N-methylformamide, propionamide, butylamide, isobutylamide, acrylamide, methacrylamide, palmitamide, stearylamide, oleamide, oxamide, glutaramide, adipamide, cinnamamide, glycolamide, lactamide, glyceramide, tartaramide, citramide, glyoxylamide, pyruvamide, acetoacetamide, dimethylacetamide, benzylamide, anthranilamide, ethylenediaminetetraacetamide, diacetamide, triacetamide, dibenzamide, tribenzamide, rhodanine, urea, 1-acetyl-2-thiourea, biuret, butylurea, dibutylurea, 1,3-dimethylurea, 1,3-diethylurea, derivatives thereof, and the like.

Examples of imide compounds include succinimide, maleimide, phthalimide, derivatives thereof, and the like.

Examples of amine compounds include methylamine, ethylamine, butylamine, ethylenediamine, glycine, alanine, valine, piperazine, piperidine, morpholine, N-methylglycine, derivatives thereof, and the like.

These polishing speed enhancers may be used alone or used as a mixture of two or more.

### <Polishing Speed Inhibitor>

Examples of polishing speed inhibitors include water-soluble polymers having a polyalkylene chain, surfactants having a polyoxyalkylene chain, and the like.

More specifically, examples of water-soluble polymers having a polyalkylene chain include polyalkylene glycols, such as polyethylene glycol, polypropylene glycol, and polybutylene glycol; and polyalkylene copolymers, such as block copolymers of oxyethylene (EO) and oxypropylene (PO) (e.g., diblock copolymer, PEO-PPO-PEO triblock copolymer, PPO-PEO-PPO triblock copolymer), random copolymers of EO and PO, and the like.

Examples of surfactants having a polyoxyalkylene chain include surfactants having 4 or more oxyalkylene units. Specific examples include non-ionic surfactants, such as polyoxyethylene propyl ether, polyoxyethylene butyl ether, polyoxyethylene pentyl ether, polyoxyethylene hexyl ether, polyoxyethylene octyl ether, polyoxyethylene-2-ethylhexyl ether, polyoxyethylene nonyl ether, polyoxyethylene decyl ether, polyoxyethylene isodecyl ether, polyoxyethylene tridecyl ether, polyoxyethylene lauryl ether, polyoxyethylene cetyl ether, polyoxyethylene stearyl ether, polyoxyethylene isostearyl ether, polyoxyethylene oleyl ether, polyoxyethylene phenyl ether, polyoxyethylene octyl phenyl ether, polyoxyethylene nonyl phenyl ether, polyoxyethylene dodecyl phenyl ether, polyoxyethylene styrenic phenyl ether, polyoxyethylene lauryl amine, polyoxyethylene stearyl amine, polyoxyethylene oleyl amine, polyoxyethylene stearyl amide, polyoxyethylene oleyl amide, polyoxyethylene monolauric acid ester, polyoxyethylene monostearic acid ester, polyoxyethylene distearic acid ester, polyoxyethylene monooleic acid ester, polyoxyethylene dioleic acid ester, polyoxyethylene sorbitan monolaurate, polyoxyethylene sorbitan monopalmitate, polyoxyethylene sorbitan monostearate, polyoxyethylene sorbitan monooleate, polyoxyethylene sorbitan trioleate, polyoxyethylene sorbitol tetraoleate, polyoxyethylene castor oil, polyoxyethylene hydrogenated castor oil; and anionic surfactants, such as polyoxyethylene lauryl ether sulfuric acid, polyoxyethylene myristyl ether sulfuric acid, polyoxyethylene palmityl ether sulfuric acid; sodium polyoxyethylene lauryl ether sulfate, ammonium polyoxyethylene lauryl ether sulfate, triethanolamine polyoxyethylene lauryl ether sulfate, sodium polyoxyethylene myristyl ether sulfate, ammonium polyoxyethylene myristyl ether sulfate, triethanolamine polyoxyethylene myristyl ether sulfate, sodium polyoxyethylene palmityl ether sulfate, amine polyoxyethylene palmityl ether sulfate, triethanolamine polyoxyethylene palmityl ether sulfate, polyoxyethylene octyl sulfonic acid, polyoxyethylene dodecyl sulfonic acid, polyoxyethylene cetyl sulfonic acid, polyoxyethylene octylbenzene sulfonic acid, polyoxyethylene dodecyl benzene sulfonic acid; sodium polyoxyethylene octyl sulfonate, sodium polyoxyethylene dodecyl sulfonate, sodium polyoxyethylene cetyl sulfonate, polyoxyethylene lauryl ether acetic acid, polyoxyethylene tridecyl ether acetic acid, polyoxyethylene octyl ether acetic acid; sodium polyoxyethylene lauryl ether acetate, ammonium polyoxyethylene lauryl ether acetate, sodium polyoxyethylene tridecyl ether acetate, ammonium polyoxyethylene tridecyl ether acetate, sodium polyoxyethylene octyl ether acetate, ammonium polyoxyethylene octyl ether acetate, polyoxyethylene lauryl ether phosphoric acid, polyoxyethylene alkyl (12-15) ether phosphoric acid; sodium polyoxyethylene lauryl ether phosphate, sodium polyoxyethylene oleyl ether phosphate, sodium polyoxyethylene cetyl ether phosphate, potassium polyoxyethylene alkyl (12-15) ether phosphate, disodium polyoxyethylene lauryl sulfosuccinate, disodium polyoxyethylene lauroyl ethanolamide sulfosuccinate, and the like.

These polishing speed inhibitors may be used alone or used as a mixture of two or more.

Among the above polishing speed adjusting agents, at least one selected from the group consisting of water-soluble polymers having a polyalkylene chain and surfactants having a polyoxyalkylene chain is preferred, and a polyalkylene glycol and a polyalkylene copolymer are more preferred. In addition, the polyalkylene glycol is more preferably at least one of polypropylene glycol and polybutylene glycol.

When the polishing speed enhancer is a water-soluble polymer, the lower limit of the weight-average molecular weight (Mw) of the polishing speed enhancer is not limited, but preferably 500 or more, more preferably 2000 or more, still more preferably 4000 or more, and yet still more preferably 6000 or more. The upper limit of the weight-average molecular weight is not limited, but preferably 1,000,000 or less, more preferably 500,000 or less, still more preferably 100,000 or less, and yet still more preferably 50,000 or less. With this range, the effect of enhancing the polishing speed is obtained efficiently.

When the polishing speed inhibitor is a water-soluble polymer, the lower limit of the weight-average molecular weight of the polishing speed inhibitor is not limited, but preferably 200 or more, more preferably 250 or more, still more preferably 300 or more, and yet still more preferably 500 or more. The upper limit of the weight-average molecular weight is not limited, but preferably 100,000 or less, more preferably 10,000 or less, still more preferably 5,000 or less, and yet still more preferably 2,000 or less. With this range, the effect of maintaining the dispersion state in water for a long time is obtained.

The weight-average molecular weight can be determined by gel permeation chromatography (GPC).

The lower limit of the amount (concentration) of the polishing speed adjusting agent in the polishing composition according to the embodiment of the present invention is not limited, but preferably 0.0001 mass % or more, more preferably 0.001 mass % or more, still more preferably 0.005 mass % or more, and yet still more preferably 0.01 mass % or more. The upper limit of the amount (concentration) of the polishing speed adjusting agent in the polishing composition according to the embodiment of the present invention is not limited, but preferably 10 mass % or less, more preferably 5 mass % or less, still more preferably 1 mass % or less, and yet still more preferably 0.5 mass % or less. In other words, the amount (concentration) of the polishing speed adjusting agent in the polishing composition is preferably 0.0001 mass % or more and 10 mass % or less, more preferably 0.05 mass % or more and 5 mass % or less, still more preferably 0.005 mass % or more and 1 mass % or less, and yet still more preferably 0.01 mass % or more and 0.5 mass % or less. With this range, the polishing speed adjusting agent is stably dispersed in water, and the effect of adjusting the polishing speed is obtained efficiently. When the polishing composition contains 2 or more polishing speed adjusting agents, the above amount refers to the total amount of 2 or more polishing speed adjusting agents.

### [Biocide]

The polishing composition according to the embodiment of the present invention contains a biocide. A biocide is also called a biocidal agent and refers to a chemical that inactivates or destroys microorganisms (viable cells). Biocides include antiseptic agents, fungicides, algicides, insecticides, repellents, and the like. These biocides may be used alone or used as a mixture of two or more. The biocide may be a commercial product or may be a synthetic product.

The biocide contained in the polishing composition according to the embodiment of the present invention includes a carbon atom, a hydrogen atom, and an oxygen atom. If a biocide having an atom (e.g., a nitrogen atom, a sulfur atom, or the like) other than the above three above atoms is used, the biocide is smaller than the polishing speed adjusting agent in terms of molecular size, and the biocide has polarity. The biocide thus acts on the silicon-silicon bonding of an object to be polished more readily than the polishing speed adjusting agent does. As a result, the silicon-silicon bonding is stretched or contracted, and the silicon-silicon bonding becomes brittle, which may result in a failure of maintaining the original polishing performance on an object to be polished containing a silicon material having silicon-silicon bonding.

The above mechanism is based on assumption, and the correctness of the assumption does not affect the technical scope of the present invention.

### <Compound Represented by Chemical Formula 1>

The biocide according to the present invention is preferably a compound represented by chemical formula 1 below.

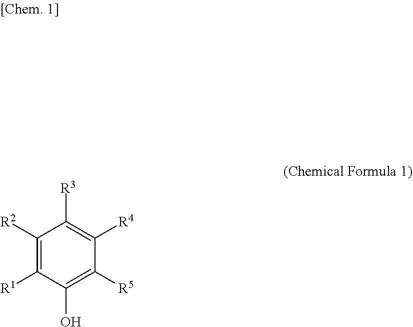

In chemical formula 1 above, R¹ to R⁵ each independently represent a hydrogen atom or a substituent including at least two atoms selected from the group consisting of a carbon atom, a hydrogen atom, and an oxygen atom.

Examples of the substituent including at least two atoms selected from the group consisting of a carbon atom, a hydrogen atom, and an oxygen atom include hydroxy group, carboxy group, C1-C20 alkyl groups, C1-C20 hydroxyalkyl groups, C1-C20 alkoxy groups, C1-C20 hydroxyalkoxy groups, C2-C21 alkoxycarbonyl groups, C6-C30 aryl groups, C7-C31 aralkyl groups (arylalkyl groups), C6-C30 aryloxy groups, C6-C30 aryloxycarbonyl groups, C8-C32 aralkyloxycarbonyl groups, C2-C20 acyl groups, C2-C20 acyloxy groups, and the like.

More specifically, examples of C1-C20 alkyl groups include linear alkyl groups, such as methyl group, ethyl group, n-propyl group, n-butyl group, n-pentyl group, n-hexyl group, n-heptyl group, n-octyl group, n-nonyl group, and n-decyl group; branched alkyl groups, such as isopropyl group, isobutyl group, s-butyl group, t-butyl group, t-amyl group, neopentyl group, 3-methylpentyl group, 1,1-diethylpropyl group, 1,1-dimethylbutyl group, 1-methyl-1-propylbutyl group, 1,1-dipropylbutyl group, 1,1-dimethyl-2-methylpropyl group, 1-methyl-1-isopropyl-2-methylpropyl group; and cyclic alkyl groups, such as cyclobutyl group, cyclopentyl group, cyclohexyl group, cycloheptyl group, cyclooctyl group, norbornenyl group, and the like.

Examples of C1-C20 hydroxyalkyl groups include hydroxymethyl group, 2-hydroxyethyl group, 2-hydroxy-n-propyl group, 3-hydroxy-n-propyl group, 2-hydroxy-n-butyl group, 3-hydroxy-n-butyl group, 4-hydroxy-n-butyl group, 2-hydroxy-n-pentyl group, 3-hydroxy-n-pentyl group, 4-hydroxy-n-pentyl group, 5-hydroxy-n-pentyl group, 2-hydroxy-n-hexyl group, 3-hydroxy-n-hexyl group, 4-hydroxy-n-hexyl group, 5-hydroxy-n-hexyl group, 6-hydroxy-n-hexyl group, and the like.

Examples of C1-C20 alkoxy groups include linear alkoxy groups, such as methoxy group, ethoxy group, n-propyloxy group, n-butyloxy group, n-pentyloxy group, n-hexyloxy group, n-heptyloxy group, n-octyloxy group, n-nonyloxy group, and n-decyloxy group; branched alkoxy groups, such as isopropyloxy group, isobutyloxy group, s-butyloxy group, t-butyloxy group, t-amyloxy group, neopentyloxy group, 3-methylpentyloxy group, 1,1-diethylpropyloxy group, 1,1-dimethylbutyloxy group, 1-methyl-1-propylbutyloxy group, 1,1-dipropylbutyloxy group, 1,1-dimethyl-2-methylpropyloxy group, 1-methyl-1-isopropyl-2-methylpropyloxy group; and cyclic alkoxy groups, such as cyclobutyloxy group, cyclopentyloxy group, cyclohexyloxy group, cycloheptyloxy group, cyclooctyloxy group, norbornenyloxy group, and the like.

Examples of C1-C20 hydroxyalkoxy groups include hydroxymethoxy group, 2-hydroxyethoxy group, 2-hydroxy-n-propyloxy group, 3-hydroxy-n-propyloxy group, 2-hydroxy-n-butyloxy group, 3-hydroxy-n-butyloxy group, 4-hydroxy-n-butyloxy group, 2-hydroxy-n-pentyloxy group, 3-hydroxy-n-pentyloxy group, 4-hydroxy-n-pentyloxy group, 5-hydroxy-n-pentyloxy group, 2-hydroxy-n-hexyloxy group, 3-hydroxy-n-hexyloxy group, 4-hydroxy-n-hexyloxy group, 5-hydroxy-n-hexyloxy group, 6-hydroxy-n-hexyloxy group, and the like.

Examples of C2-C21 alkoxycarbonyl groups include methoxycarbonyl group, ethoxycarbonyl group, propoxycarbonyl group, butoxycarbonyl group, pentyloxycarbonyl group, hexyloxycarbonyl group, octyloxycarbonyl group, decyloxycarbonyl group, and the like.

Examples of C6-C30 aryl groups include phenyl group, naphthyl group, anthranil group, pyrenyl group, and the like.

Examples of C7-C31 aralkyl groups (arylalkyl groups) include benzyl group and phenethyl group (phenylethyl group). Examples of C6-C30 aryloxy groups include phenyloxy group (phenoxy group), naphthyloxy group, anthraniloxy group, pyrenyloxy group, and the like.

Examples of C7-C31 aryloxycarbonyl groups include phenyloxycarbonyl group, naphthyloxycarbonyl group, anthraniloxycarbonyl group, pyrenyloxycarbonyl group, and the like.

Examples of C8-C32 aralkyloxycarbonyl groups include benzyloxycarbonyl group, phenethyloxycarbonyl group, and the like.

Examples of C2-C21 acyl groups include methanoyl group (formyl group), ethanoyl group (acetyl group), propanoyl group, butanoyl group, pentanoyl group, hexanoyl group, octanoyl group, decanoyl group, benzoyl group, and the like.

Examples of C2-C20 acyloxy groups include formyloxy group, acetyloxy group, propanoyloxy group, butanoyloxy group, pentanoyloxy group, hexanoyloxy group, octanoyloxy group, decanoyloxy group, benzoyloxy group, and the like.

Furthermore, the biocide represented by chemical formula 1 above is preferably at least one selected from the group consisting of compounds represented by chemical formulas 1-a to 1-c below.

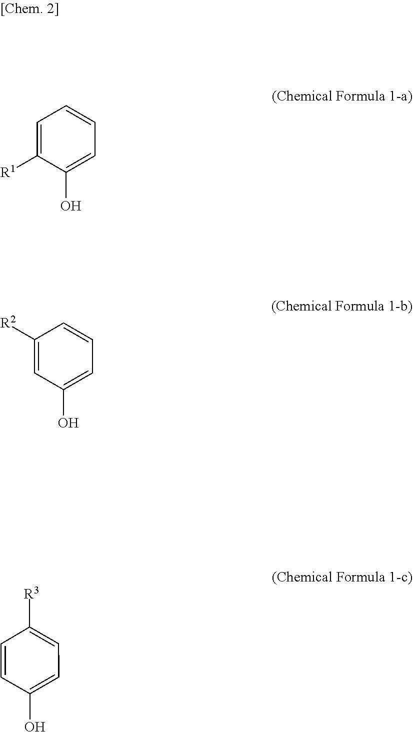

In chemical formula 1 above, R¹ to R³ each independently represent a substituent including at least two atoms selected from the group consisting of a carbon atom, a hydrogen atom, and an oxygen atom.

Examples of the substituent including at least two atoms selected from the group consisting of a carbon atom, a hydrogen atom, and an oxygen atom are the same as those described above, and description of the substituent is omitted here.

Specific examples of the compound represented by chemical formula 1 above include paraoxybenzoic acid esters (parahydroxybenzoic acid esters), such as methyl paraoxybenzoate (methyl parahydroxybenzoate), ethyl paraoxybenzoate (ethyl parahydroxybenzoate), butyl paraoxybenzoate (butyl parahydroxybenzoate), benzyl paraoxybenzoate (benzyl parahydroxybenzoate); and salicylic acid, methyl salicylate, phenol, catechol, resorcinol, hydroquinone, isopropylphenol, cresol, thymol, phenoxyethanol, phenylphenol (2-phenylphenol, 3-phenylphenol, 4-phenylphenol), 2-phenylethyl alcohol (phenethyl alcohol), and the like.

Among these, the compound represented by chemical formula 1 above is preferably at least one selected from the group consisting of ethyl paraoxybenzoate, butyl paraoxybenzoate, and phenylphenol, and more preferably butyl paraoxybenzoate in order to effectively obtain desired advantageous effects of the present invention.

### <Unsaturated Fatty Acid>

The biocide used in the present invention is also preferably an unsaturated fatty acid. Examples of the unsaturated fatty acid include mono-unsaturated fatty acids, such as crotonic acid, myristoleic acid, palmitoleic acid, oleic acid, and ricinoleic acid; di-unsaturated fatty acids, such as sorbic acid, linoleic acid, and eicosadienoic acid; tri-unsaturated fatty acids, such as linolenic acid, pinolenic acid, and eleostearic acid; tetra-unsaturated fatty acids, such as stearidonic acid and arachidonic acid; penta-unsaturated fatty acids, such as bosseopentaenoic acid and eicosapentaenoic acid; hexa-unsaturated fatty acids, such as docosahexaenoic acid and nisinic acid; and the like.

Among these, the unsaturated fatty acid is preferably sorbic acid in order to effectively obtain desired advantageous effects of the present invention.

In addition to the above compounds, the following compounds can also be used as the biocide according to the present invention: for example, 1,2-alkanediols, such as 1,2-pentanediol, 1,2-hexanediol, and 1,2-octanediol; alkyl glyceryl ethers, such as 2-ethylhexyl glyceryl ether (ethylhexylglycerin); and capric acid, dehydroacetic acid, and the like.

The lower limit of the amount (concentration) of the biocide in the polishing composition according to the embodiment of the present invention is not limited, but preferably 0.0001 mass % or more, more preferably 0.001 mass % or more, still more preferably 0.005 mass % or more, and yet still more preferably 0.01 mass % or more. The upper limit of the amount (concentration) of the biocide in the polishing composition according to the embodiment of the present invention is not limited, but preferably 5 mass % or less, more preferably 1 mass % or less, still more preferably 0.5 mass % or less, and yet still more preferably 0.1 mass % or less. In other words, the amount (concentration) of the biocide in the polishing composition is preferably 0.0001 mass % or more and 5 mass % or less, more preferably 0.001 mass % or more and 1 mass % or less, still more preferably 0.005 mass % or more and 0.5 mass % or less, and yet still more preferably 0.01 mass % or more and 0.1 mass % or less.

With this range, the effect of inactivating or destroying microorganisms is adequately obtained. When the polishing composition contains 2 or more biocides, the above amount refers to the total amount of 2 or more biocides.

### [Dispersing Medium]

The polishing composition according to the present invention preferably contains a dispersing medium in order to disperse each component contained in the polishing composition. Examples of the dispersing medium include organic solvents and water. Among these, water is preferably contained.

The dispersing medium is preferably water containing as few impurities as possible in order to suppress contamination of an object to be polished and inhibition of the action of other components. As such water, for example, water having a total amount of transition metal ions of 100 ppb or less is preferred. The purity of water can be increased by, for example, operations, such as removal of impurity ions using ion exchange resin, removal of foreign matters with a filter, and distillation. Specifically, for example, deionized water (ion exchange water), pure water, ultrapure water, distilled water, or the like is preferably used as water. Normally, water preferably constitutes 90% by volume or more of the dispersing medium contained in the polishing composition, more preferably constitutes 95% by volume or more of the dispersing medium, still more preferably constitutes 99% by volume or more of the dispersing medium, and yet still more preferably constitutes 100% by volume of the dispersing medium.

### [pH of Polishing Composition]

The pH of the polishing composition according to the present invention is not limited, but preferably lower than 7 (lower than 7.0). If the pH is 7 or higher (7.0 or higher), the polishing speed for an object to be polished may decrease. The pH is preferably 6.5 or lower, more preferably 6 or lower (6.0 or lower), still more preferably 5.5 or lower, and yet still more preferably 5 or lower (5.0 or lower). The lower limit of the pH is preferably 1 or higher (1.0 or higher), more preferably 2 or higher (2.0 or higher), still more preferably 3 or higher (3.0 or higher), yet still more preferably higher than 3.5, and yet still more preferably 3.8 or higher.

The pH of the polishing composition can be measured by the method described in Examples.

### <pH Adjusting Agent>

To adjust the pH to the above range, the polishing composition according to the present invention may further contain a pH adjusting agent.

As the pH adjusting agent, a known acid, a known base, or a salt thereof can be used. Specific examples of acids that can be used as a pH adjusting agent include inorganic acids, such as hydrochloric acid, sulfuric acid, nitric acid, hydrofluoric acid, boric acid, carbonic acid, hypophosphorous acid, phosphorous acid, and phosphoric acid; and organic acids, such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, phenoxyacetic acid, and the like.

Specific examples of bases that can be used as a pH adjusting agent include aliphatic amines, such as ethanolamine and 2-amino-2-ethyl-1,3-propanediol; amines, such as aromatic amines; organic bases, such as quaternary ammonium hydroxide; hydroxides of alkali metals, such as potassium hydroxide; and hydroxides of group 2 metals, tetramethylammonium hydroxide, and ammonia.

These pH adjusting agents may be used alone or used as a mixture of two or more.

In combination with the above acid, an alkali metal salt, such as an ammonium salt, sodium salt, or potassium salt of the above acid, may be used as a pH buffering agent.

The amounts of the pH adjusting agent and the pH buffering agent added are not limited and may be appropriately adjusted such that the pH of the polishing composition is in a desired range.

### [Other Additives]

The polishing composition according to the present invention may further contain known additives, such as a chelating agent, a thickener, an oxidizing agent, a dispersant, a surface protection agent, a wetting agent, a surfactant, and a dissolution aid, unless the advantageous effects of the present invention are impaired. The amounts of the additives may be appropriately set according to the purpose of addition. Hereinafter, a dissolution aid, which is a preferred additive, will be described.

### <Dissolution Aid>

A dissolution aid is a substance that, when the biocide according to the present invention is dissolved in a dispersing medium (solvent), is present together with the biocide to improve the solubility of the biocide. The polishing composition according to the embodiment of the present invention preferably further contains a dissolution aid.

Examples of the dissolution aid include alcohol compounds, such as methanol, ethanol, 1-propanol, 2-propanol, ethylene glycol, and propylene glycol; ether compounds, such as diethylene glycol diethyl ether, 2-methoxyethanol, 2-ethoxyethanol, diethylene glycol, diethylene glycol monomethyl ether, diethylene glycol monoethyl ether, diethylene glycol monobutyl ether, triethylene glycol, triethylene glycol monomethyl ether, tetraethylene glycol, dipropylene glycol, dipropylene glycol monomethyl ether, dipropylene glycol monoethyl ether, tripropylene glycol monomethyl ether, diacetone alcohol, 2-methoxyethyl acetate, 2-ethoxyethyl acetate, and diethylene glycol monoethyl ether acetate; and ketone compounds, such as acetone, methyl ethyl ketone, acetylacetone, cyclohexanone, and the like. These dissolution aids may be used alone or used as a mixture of two or more.

The lower limit of the amount (concentration) of the dissolution aid in the polishing composition according to the embodiment of the present invention is not limited, but preferably 0.05 mass % or more, more preferably 0.1 mass % or more, and still more preferably 0.5 mass % or more. The upper limit of the amount (concentration) of the dissolution aid in the polishing composition according to the embodiment of the present invention is not limited, but preferably 10 mass % or less, more preferably 5 mass % or less, and still more preferably 4 mass % or less. In other words, the amount (concentration) of the dissolution aid in the polishing composition is preferably 0.05 mass % or more and 10 mass % or less, more preferably 0.1 mass % or more and 5 mass % or less, and still more preferably 0.5 mass % or more and 4 mass % or less. With this range, the biocide can be stably dispersed in water. When the polishing composition contains 2 or more dissolution aids, the above amount refers to the total amount of 2 or more dissolution aids.

### [Polishing Composition Manufacturing Method]

The method for manufacturing the polishing composition according to the present invention is not limited. For example, the polishing composition can be produced by mixing silica particles, a polishing speed adjusting agent, a biocide, and as necessary, other additives in a dispersing medium under stirring. The details of each component are as described above.

The temperature at which the components are mixed is not limited but preferably 10° C. or higher and 40° C. or lower. Heating may be performed in order to increase the rate of dissolution. The mixing time is not limited as long as uniform mixing is achieved.

### <Polishing Method and Semiconductor Substrate Manufacturing Method>

The present invention provides a polishing method including polishing an object to be polished containing a silicon material having silicon-silicon bonding by using the polishing composition according to the embodiment of the present invention. The present invention also provides a semiconductor substrate manufacturing method including the polishing method.

As a polishing apparatus, a common polishing apparatus that is provided with a holder for holding a substrate having an object to be polished or the like, a motor with variable rotation speed, and the like and that has a polishing table to which a polishing pad (polishing cloth) can be attached can be used.

As the polishing pad, a common nonwoven fabric, polyurethane, a porous fluorocarbon resin, or the like can be used without any limitation. The polishing pad is preferably processed so as to have a groove in which a polishing liquid is collected.

Regarding polishing conditions, for example, the rotation speed of the polishing table is preferably 10 rpm (0.17 s⁻¹) or higher and 500 rpm (8.3 s⁻¹) or lower.

The pressure (polishing pressure) applied to the substrate having an object to be polished is preferably 0.5 psi (3.4 kPa) or higher and 10 psi (68.9 kPa) or lower. The method for supplying the polishing composition to the polishing pad is not limited either. For example, a method for continuously supplying the polishing composition by using a pump or the like is employed. The amount of the polishing composition supplied is not limited, but it is preferred that the surface of the polishing pad be always covered with the polishing composition according to the present invention.

After the polishing is complete, the substrate is washed with running water, and water drops attached to the substrate are shaken off and dried by a spin dryer or the like, thereby providing a substrate having a metal-containing layer.

The polishing composition according to the present invention may be of one-pack type or may be of multi-pack type including two-pack type. The polishing composition according to the present invention may be prepared by diluting a stock solution of the polishing composition, for example, 10 or more times with a diluent, such as water.

Although the embodiments of the present invention are described in detail, these are descriptive and illustrative and should not be construed as limiting, and it is apparent that the scope of the present invention is defined by the appended claims.

The present invention includes the following aspects and embodiments.

1. A polishing composition containing silica particles, a polishing speed adjusting agent for an object to be polished containing a silicon material having silicon-silicon bonding, and a biocide,

wherein the biocide includes a carbon atom, a hydrogen atom, and an oxygen atom;

2. The polishing composition according to 1. above, wherein the silica particles are cationically modified silica particles;

3. The polishing composition according to 1. or 2. above, wherein the biocide is a compound represented by chemical formula 1 below;

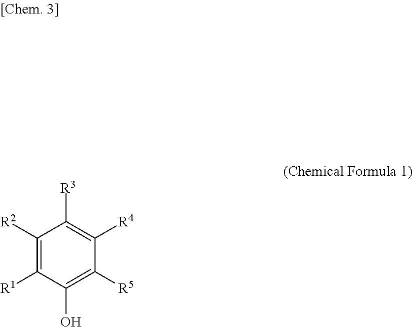

in chemical formula 1 above, R¹ to R⁵ each independently represent a hydrogen atom or a substituent including at least two atoms selected from the group consisting of a carbon atom, a hydrogen atom, and an oxygen atom;

4. The polishing composition according to 3. above, wherein the biocide is at least one selected from the group consisting of compounds represented by chemical formulas 1-a to 1-c below;

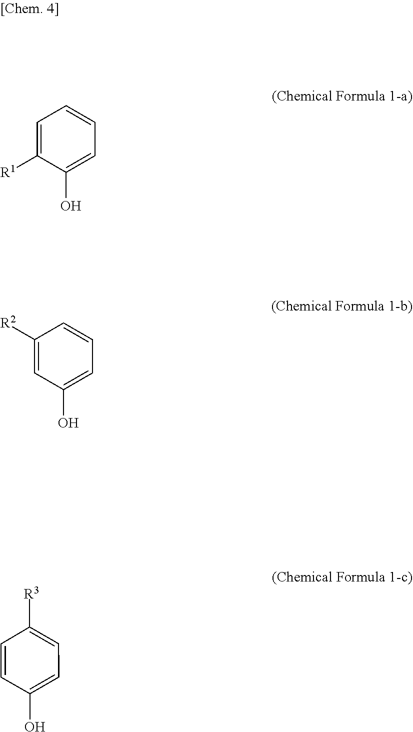

in chemical formula 1 above, R¹ to R³ each independently represent a substituent including at least two atoms selected from the group consisting of a carbon atom, a hydrogen atom, and an oxygen atom;

5. The polishing composition according to 3. or 4. above, wherein the biocide is at least one selected from the group consisting of ethyl paraoxybenzoate, butyl paraoxybenzoate, and phenylphenol;

6. The polishing composition according to 1. or 2. above, wherein the biocide is an unsaturated fatty acid;

7. The polishing composition according to 6. above, wherein the unsaturated fatty acid is sorbic acid;

8. The polishing composition according to any one of 1. to 7. above, wherein the polishing speed adjusting agent for an object to be polished containing a silicon material having the silicon-silicon bonding is at least one selected from the group consisting of a water-soluble polymer having a polyalkylene chain and a surfactant having a polyoxyalkylene chain;

9. The polishing composition according to 8. above, wherein the water-soluble polymer having a polyalkylene chain is at least one selected from the group consisting of a polyalkylene glycol and a polyalkylene copolymer;

10. The polishing composition according to 9. above, wherein the polyalkylene glycol is at least one of polypropylene glycol and polybutylene glycol;

11. The polishing composition according to any one of 1. to 10. above, wherein the polishing composition has a pH of higher than 3.5; 12. The polishing composition according to any one of 1. to 11. above, further containing a dissolution aid for the biocide; and

13. A polishing method including polishing an object to be polished containing a silicon material having silicon-silicon bonding by using the polishing composition according to any one of 1. to 12. above.

### EXAMPLES

The present invention will be described in more detail by way of the following Examples and Comparative Examples. However, the technical scope of the present invention is not limited to the following Examples. Unless otherwise specified, the units “%” and “part” mean “mass %” and “parts by mass”, respectively. In the following Examples, unless otherwise specified, the operation was carried out under the conditions of room temperature (20° C. or higher and 25° or lower)/relative humidity of 40% RH or higher and 50% RH or lower.

### <Preparation of Silica Particles>

As cationically modified silica, amino group-modified colloidal silica having an average primary particle size of 31 nm, an average secondary particle size of 62 nm, and an average association degree of 2.0 was prepared. As anionically modified silica, sulfonic acid-modified colloidal silica (produced by the method described in “Sulfonic acid-functionalized silica through quantitative oxidation of thiol groups”, Chem. Commun. 246-247 (2003), average primary particle size 32 nm, average secondary particle size 69 nm, average association degree 2.2) was prepared.

The average primary particle size of the silica particles was calculated from the density of the silica particles and the specific surface area of the silica particles in accordance with a BET method as measured by using “Flow Sorb II 2300” available from Micromeritics Instruments Corporation. The average secondary particle size of the silica particles was measured by using a dynamic light scattering particle size/particle size distribution analyzer UPA-UTI151 available from Nikkiso Co., Ltd.

### Preparation of Polishing Composition

### Example 1

To water serving as a dispersing medium were added: cationically modified silica serving as silica particles in an amount of 0.25 mass % relative to the total amount of the polishing composition, polyethylene glycol (weight-average molecular weight (Mw): 600) serving as a polishing speed adjusting agent in an amount of 0.01 mass % relative to the total amount of the polishing composition, ethyl paraoxybenzoate serving as a biocide in an amount of 0.03 mass % relative to the total amount of the polishing composition, and ethanol serving as a dissolution aid in an amount of 0.5 mass % relative to the total amount of the polishing composition.

Subsequently, tartaric acid serving as a pH adjusting agent was added such that the pH became 4 (higher than 3.5 and lower than 4.5), and the resulting mixture was mixed under stirring at room temperature (25° C.) for 30 minutes to prepare a polishing composition.

The pH of the polishing composition (liquid temperature: 25° C.) was checked with a pH meter (available from Horiba Ltd., model: LAQUA).

### Examples 2 to 15, Comparative Examples 1 to 13

Each polishing composition was prepared in the same manner as in Example 1 except that the type of silica particles, the type of polishing speed adjusting agent (polishing speed inhibitor), the type and amount of biocide, and the type and amount of dissolution aid were changed as described in Table 1 below. In Table 1, “-” denotes that agent is not used.

### [Evaluation]

As an object to be polished, a silicon wafer (200 mm, blanket wafer: available from Advantech Co., Ltd) having a 5000-Å-thick polysilicon (Poly-Si) film on the surface was prepared. The substrate was polished under the following polishing conditions by using each polishing composition prepared as described above.

### <Antiseptic Performance>

To evaluate the antiseptic performance of each polishing composition, the test involving forcibly adding microorganisms and culturing them for a certain period of time was carried out as described below. Two grams of industrial water inoculated with an inoculum (total cell number 10⁸ cells/mL or more) was added to 50 g of each polishing composition, and the resulting polishing composition was left to stand at 35° C. for 5 days or 10 days. Thereafter, the number of viable cells under the culture conditions at 35° C. for 5 days or 10 days was counted by using a biochecker (model: San-Ai Biochecker-TTC) available from San-Ai Oil Co., Ltd.

### <Polishing Speed (Removal Rate)>

### (Polishing Conditions)

Mirra (available from Applied Materials, Inc.) was used as a polishing machine, IC1000 (available from Rohm and Haas Company) as a polishing pad, and A165 (available from 3M Company) as a conditioner for the polishing pad. Polishing was performed under the conditions of a polishing pressure of 4.0 psi (27.59 kPa), a table rotation speed of 123 rpm, a head rotation speed of 117 rpm, and a polishing composition supply rate of 130 ml/min for a polishing time of 60 seconds. Pad conditioning with the conditioner was performed in-situ at a rotation speed of 120 rpm and a pressure of 5 lbf (22.24 N) during polishing.

The polishing speed (removal rate (RR)) was calculated in accordance with the following formula. It is noted that 1 Å=0.1 nm.

Polishing Speed [Å/min]=(film thickness [Å] before polishing−film thickness [Å] after polishing)/polishing time [min] [Formula 1]

The film thickness was determined by using a light interference type film thickness measurement apparatus (available from KLA-Tencor Corporation, model: ASET-f5x), and the polishing speed was evaluated by dividing a difference in film thickness between before and after polishing by the polishing time.

### <Solubility of Biocide>

One liter of each polishing composition was stored at 0° C. for 24 hours and then filtered under suction through a membrane filter under the following conditions. The conditions of the filter after drying were visually observed.

### [Filtration Conditions]

Filter used: type: membrane filter ((47 mm, disc shape) available from Toyo Roshi Kaisha, Ltd.

material: mixed cellulose ester

pore size: 1.0 μm

Suction pump: portable aspirator MDA-015 available from ULVAC KIKO, Inc.

### [Evaluation Criteria]

Incomplete dissolution: scale-like precipitates originated from the biocide are visually observed on the membrane filter after drying.

Good: no scale-like precipitates originated from the biocide are visually observed on the membrane filter after drying.

-: no data because no biocide is added.

The components of each polishing composition and the evaluation results are shown in Table 1 and Table 2 below, respectively.

TABLE 1

| | | | Polishing Speed | | | | | | | |
|---|---|---|---|---|---|---|---|---|---|---|
| | Silica Particles | | Adjusting Agent | | Biocide | | Dissolution Aid | | pH | |
| | | Amount | | Amount | | Amount | | Amount | Adjusting | |
| | Type | (mass %) | Type | (mass %) | Type | (mass %) | Type | (mass %) | Agent | pH |
| Example 1 | cationically | 0.25 | polyethylene | 0.01 | ethyl | 0.03 | ethanol | 0.5 | tartaric | 4 |
| | modified silica | | glycol Mw 600 | | paraoxybenzoate | | | | acid | |
| Example 2 | cationically | 0.25 | polyethylene | 0.01 | ethyl | 0.03 | dipropylene | 1.0 | tartaric | 4 |
| | modified silica | | glycol Mw 600 | | paraoxybenzoate | | glycol | | acid | |
| | | | | | | | monomethyl | | | |
| | | | | | | | ether | | | |
| Example 3 | cationically | 0.25 | polyethylene | 0.01 | ethyl | 0.01 | ethanol | 0.8 | tartaric | 4 |
| | modified silica | | glycol Mw 600 | | paraoxybenzoate | | | | acid | |
| Example 4 | cationically | 0.25 | polyethylene | 0.01 | sorbic acid | 0.05 | dipropylene | 1.0 | tartaric | 4 |
| | modified silica | | glycol Mw 600 | | | | glycol | | acid | |
| | | | | | | | monomethyl | | | |
| | | | | | | | ether | | | |
| Example 5 | cationically | 0.25 | polyethylene | 0.01 | methyl salicylate | 0.05 | dipropylene | 1.0 | tartaric | 4 |
| | modified silica | | glycol Mw 600 | | | | glycol | | acid | |
| | | | | | | | monomethyl | | | |
| | | | | | | | ether | | | |
| Example 6 | cationically | 0.25 | polyethylene | 0.01 | ethyl | 0.03 | ethanol | 0.5 | tartaric | 4 |
| | modified silica | | glycol Mw 400 | | paraoxybenzoate | | | | acid | |
| Example 7 | cationically | 0.25 | polypropylene | 0.01 | ethyl | 0.03 | ethanol | 0.5 | tartaric | 4 |
| | modified silica | | glycol Mw 420 | | paraoxybenzoate | | | | acid | |
| Example 8 | cationically | 0.25 | polypropylene | 0.01 | ethyl | 0.03 | ethanol | 0.5 | tartaric | 4 |
| | modified silica | | glycol Mw 750 | | paraoxybenzoate | | | | acid | |
| Example 9 | cationically | 0.25 | polypropylene | 0.01 | 2-phenylphenol | 0.03 | dipropylene | 1.0 | tartaric | 4 |
| | modified silica | | glycol Mw 750 | | | | glycol | | acid | |
| | | | | | | | monomethyl | | | |
| | | | | | | | ether | | | |
| Example 10 | anionically | 0.25 | polyethylene | 0.01 | ethyl | 0.03 | ethanol | 0.5 | tartaric | 4 |
| | modified silica | | glycol Mw 600 | | paraoxybenzoate | | | | acid | |
| Example 11 | anionically | 0.25 | polypropylene | 0.01 | ethyl | 0.03 | ethanol | 0.5 | tartaric | 4 |
| | modified silica | | glycol Mw 420 | | paraoxybenzoate | | | | acid | |
| Example 12 | cationically | 0.25 | polypropylene | 0.01 | benzyl | 0.01 | ethanol | 3.0 | tartaric | 4 |
| | modified silica | | glycol Mw 420 | | paraoxybenzoate | | | | acid | |
| Example 13 | cationically | 0.25 | polypropylene | 0.01 | capric acid | 0.1 | ethanol | 3.0 | tartaric | 4 |
| | modified silica | | glycol Mw 420 | | | | | | acid | |
| Example 14 | cationically | 0.25 | polyethylene | 0.01 | sorbic acid | 0.03 | dipropylene | 1.0 | tartaric | 4 |
| | modified silica | | glycol Mw 600 | | | | glycol | | acid | |
| | | | | | | | monomethyl | | | |
| | | | | | | | ether | | | |
| Example 15 | cationically | 0.25 | polybutylene | 0.01 | ethyl | 0.03 | ethanol | 0.5 | tartaric | 4 |
| | modified silica | | glycol Mw 650 | | paraoxybenzoate | | | | acid | |
| Comparative | cationically | 0.25 | — | — | — | — | — | — | tartaric | 4 |
| Example 1 | modified silica | | | | | | | | acid | |
| Comparative | cationically | 0.25 | polyethylene | 0.01 | — | 0.015 | — | — | tartaric | 4 |
| Example 2 | modified silica | | glycol Mw 600 | | | | | | acid | |
| Comparative | cationically | 0.25 | — | — | 2-methyl-4- | 0.001 | — | — | tartaric | 4 |
| Example 3 | modified silica | | | | isothiazolin-3-one | | | | acid | |
| Comparative | cationically | 0.25 | polyethylene | 0.01 | 2-methyl-4- | 0.015 | — | — | tartaric | 4 |
| Example 4 | modified silica | | glycol Mw 600 | | isothiazolin-3-one | | | | acid | |
| Comparative | cationically | 0.25 | polyethylene | 0.01 | 2-methyl-4- | 0.01 | — | — | tartaric | 4 |
| Example 5 | modified silica | | glycol Mw 600 | | isothiazolin-3-one | | | | acid | |
| Comparative | cationically | 0.25 | polyethylene | 0.01 | 1,2-benzisothiazolin- | 0.01 | — | — | tartaric | 4 |
| Example 6 | modified silica | | glycol Mw 600 | | 3-one | | | | acid | |
| Comparative | cationically | 0.25 | polyethylene | 0.01 | 5-chloro-2-methyl- | 0.015 | — | — | tartaric | 4 |
| Example 7 | modified silica | | glycol Mw 600 | | 4-isothiazolin-3-one | | | | acid | |
| Comparative | cationically | 0.25 | polyethylene | 0.01 | 2-pyridinethiol-1- | 0.015 | — | — | tartaric | 4 |
| Example 8 | modified silica | | glycol Mw 600 | | oxide | | | | acid | |
| Comparative | cationically | 0.25 | — | — | ethyl paraoxybenzoate | 0.015 | — | — | tartaric | 4 |
| Example 9 | modified silica | | | | | | | | acid | |
| Comparative | anionically | 0.25 | — | — | — | — | — | — | tartaric | 4 |
| Example 10 | modified silica | | | | | | | | acid | |
| Comparative | anionically | 0.25 | polyethylene | 0.01 | — | — | — | — | tartaric | 4 |
| Example 11 | modified silica | | glycol Mw 600 | | | | | | acid | |
| Comparative | anionically | 0.25 | — | — | 2-methyl-4- | 0.015 | — | — | tartaric | 4 |
| Example 12 | modified silica | | | | isothiazolin-3-one | | | | acid | |
| Comparative | anionically | 0.25 | polyethylene | 0.01 | 2-methyl-4- | 0.015 | — | — | tartaric | 4 |
| Example 13 | modified silica | | glycol Mw 600 | | isothiazolin-3-one | | | | acid | |

TABLE 2

| | Antiseptic | Antiseptic | Poly-Si | |
|---|---|---|---|---|
| | Performance | Performance | Polishing | Solubility |
| | (cells/ml) | (cells/ml) | Speed | of |
| | After 5 Days | After 10 Days | (Å/min) | Biocide |
| Example 1 | not detected | not detected | 24 | good |
| Example 2 | not detected | not detected | 24 | good |
| Example 3 | not detected | not detected | 20 | good |
| Example 4 | not detected | not detected | 26 | good |
| Example 5 | not detected | not detected | 27 | good |
| Example 6 | not detected | not detected | 35 | good |
| Example 7 | not detected | not detected | 13 | good |
| Example 8 | not detected | not detected | 9 | good |
| Example 9 | not detected | not detected | 22 | good |
| Example 10 | not detected | not detected | 27 | good |
| Example 11 | not detected | not detected | 20 | good |
| Example 12 | not detected | not detected | 25 | good |
| Example 13 | not detected | not detected | 26 | good |
| Example 14 | not detected | 10² or more | 26 | good |
| Example 15 | not detected | not detected | 21 | good |
| Comparative | 10⁸ or more | 10⁸ or more | 252 | — |
| Example 1 | | | | |
| Comparative | 10⁸ or more | 10⁸ or more | 20 | — |
| Example 2 | | | | |
| Comparative | not detected | not detected | 391 | good |
| Example 3 | | | | |
| Comparative | 10⁸ or more | 10⁸ or more | 156 | good |
| Example 4 | | | | |
| Comparative | not detected | not detected | 207 | good |
| Example 5 | | | | |
| Comparative | not detected | not detected | 211 | good |
| Example 6 | | | | |
| Comparative | not detected | not detected | 200 | good |
| Example 7 | | | | |
| Comparative | not detected | not detected | 198 | good |
| Example 8 | | | | |
| Comparative | 10⁸ or more | 10⁸ or more | 251 | incomplete |
| Example 9 | | | | dissolution |
| Comparative | 10⁸ or more | 10⁸ or more | 282 | — |
| Example 10 | | | | |
| Comparative | 10⁸ or more | 10⁸ or more | 26 | — |
| Example 11 | | | | |
| Comparative | not detected | not detected | 364 | good |
| Example 12 | | | | |
| Comparative | not detected | not detected | 211 | good |
| Example 13 | | | | |

Tables 1 to 2 show that the polishing compositions according to Examples 1 to 15 can maintain the original polishing performance on an object to be polished so as to suppress proliferation of viable cells and reduce the polishing speed for an object to be polished compared with the polishing compositions according to Comparative Examples.

It is also found that the compound represented by chemical formula 1 is better than unsaturated fatty acid in order to maintain the original polishing performance, that is, reduce the polishing speed for an object to be polished (comparison between Examples 3 and 4). In the case of the polishing composition according to Example 14 having lower sorbic acid content than the polishing composition according to Example 4, the phenomenon in which the antiseptic performance slightly deteriorated after 10 days was observed.

In addition, it is found that benzyl paraoxybenzoate and capric acid need a larger amount of dissolution aid because of poor solubility in water (see the compositions according to Examples 12 and 13).

### Examples 16 to 19, Comparative Examples 14 to 21

Each polishing composition was prepared in the same manner as in Example 1 except that the type of silica particles, the type and amount of polishing speed adjusting agent (polishing speed enhancer), the type and amount of biocide, and the type of dissolution aid were changed as described in Table 3 below. In Table 3, “-” denotes that agent is not used.

Each polishing composition thus obtained was evaluated for its antiseptic performance, polishing speed, and solubility of biocide by the same methods as described above.

The components of each polishing composition and the evaluation results are shown in Table 3 and Table 4 below, respectively.

TABLE 3

| | | | Polishing Speed | | | | | | | |
|---|---|---|---|---|---|---|---|---|---|---|
| | Silica Particles | | Adjusting Agent | | Biocide | | Dissolution Aid | | pH | |
| | | Amount | | Amount | | Amount | | Amount | Adjusting | |
| | Type | (mass %) | Type | (mass %) | Type | (mass %) | Type | (mass %) | Agent | PH |
| Example 16 | cationically | 0.25 | polyvinyl | 0.01 | ethyl paraoxybenzoate | 0.03 | ethanol | 0.5 | tartaric acid | 4 |
| | modified silica | | alcohol Mw 8800 | | | | | | | |
| Example 17 | cationically | 0.25 | nicotinamide | 0.1 | ethyl paraoxybenzoate | 0.03 | ethanol | 0.5 | tartaric acid | 4 |
| | modified silica | | | | | | | | | |
| Example 18 | anionically | 0.25 | polyvinyl | 0.01 | ethyl paraoxybenzoate | 0.03 | ethanol | 0.5 | tartaric acid | 4 |
| | modified silica | | alcohol Mw 8800 | | | | | | | |
| Example 19 | anionically | 0.25 | nicotinamide | 0.1 | ethyl paraoxybenzoate | 0.03 | ethanol | 0.5 | tartaric acid | 4 |
| | modified silica | | | | | | | | | |
| Comparative | cationically | 0.25 | polyvinyl | 0.01 | — | — | — | — | tartaric acid | 4 |
| Example 14 | modified silica | | alcohol Mw 8800 | | | | | | | |
| Comparative | cationically | 0.25 | nicotinamide | 0.1 | — | — | — | — | tartaric acid | 4 |
| Example 15 | modified silica | | | | | | | | | |
| Comparative | anionically | 0.25 | polyvinyl | 0.01 | — | — | — | — | tartaric acid | 4 |
| Example 16 | modified silica | | alcohol Mw 8800 | | | | | | | |
| Comparative | anionically | 0.25 | nicotinamide | 0.1 | — | — | — | — | tartaric acid | 4 |
| Example 17 | modified silica | | | | | | | | | |
| Comparative | cationically | 0.25 | polyvinyl | 0.01 | 2-methyl-4- | 0.015 | — | — | tartaric acid | 4 |
| Example 18 | modified silica | | alcohol Mw 8800 | | isothiazolin-3-one | | | | | |
| Comparative | cationically | 0.25 | nicotinamide | 0.1 | 2-methyl-4 | 0.015 | — | — | tartaric acid | 4 |
| Example 19 | modified silica | | | | isothiazolin-3-one | | | | | |
| Comparative | anionically | 0.25 | polyvinyl | 0.01 | 2-methyl-4- | 0.015 | — | — | tartaric acid | 4 |
| Example 20 | modified silica | | alcohol Mw 8800 | | isothiazolin-3-one | | | | | |
| Comparative | anionically | 0.25 | nicotinamide | 0.1 | 2-methyl-4 | 0.015 | — | — | tartaric acid | 4 |
| Example 21 | modified silica | | | | isothiazolin-3-one | | | | | |

TABLE 4

| | Antiseptic | Antiseptic | Poly-Si | |
|---|---|---|---|---|
| | Performance | Performance | Polishing | Solubility |
| | (cells/ml) | (cells/ml) | Speed | of |
| | After 5 Days | After 10 Days | (Å/min) | Biocide |
| Example 16 | not detected | not detected | 421 | good |
| Example 17 | not detected | not detected | 759 | good |
| Example 18 | not detected | not detected | 478 | good |
| Example 19 | not detected | not detected | 920 | good |
| Comparative | 10⁸ or more | 10⁸ or more | 422 | — |
| Example 14 | | | | |
| Comparative | 10⁸ or more | 10⁸ or more | 755 | — |
| Example 15 | | | | |
| Comparative | 10⁸ or more | 10⁸ or more | 481 | — |
| Example 16 | | | | |
| Comparative | 10⁸ or more | 10⁸ or more | 901 | — |
| Example 17 | | | | |
| Comparative | not detected | not detected | 301 | good |
| Example 18 | | | | |
| Comparative | not detected | not detected | 645 | good |
| Example 19 | | | | |
| Comparative | not detected | not detected | 389 | good |
| Example 20 | | | | |
| Comparative | not detected | not detected | 782 | good |
| Example 21 | | | | |

Tables 3 to 4 show that the polishing compositions according to Examples 16 to 19 can maintain the original polishing performance on an object to be polished so as to suppress proliferation of viable cells and enhance the polishing speed for an object to be polished compared with the polishing compositions according to Comparative Examples 14 to 21.

What is claimed is:

1. A polishing composition comprising: silica particles; a polishing speed adjusting agent for an object to be polished containing a silicon material having silicon-silicon bonding; and a biocide,
wherein the biocide includes a carbon atom, a hydrogen atom, and an oxygen atom.

2. The polishing composition according to claim 1, wherein the silica particles are cationically modified silica particles.

3. The polishing composition according to claim 1, wherein the biocide is a compound represented by chemical formula 1 below: 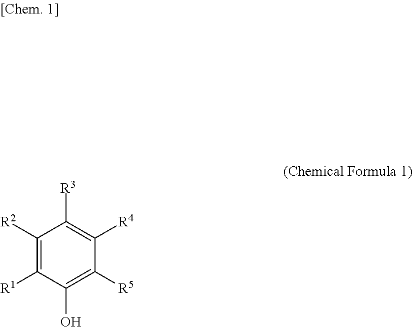
wherein, in chemical formula 1 above, R¹ to R⁵ each independently represent a hydrogen atom or a substituent including at least two atoms selected from the group consisting of a carbon atom, a hydrogen atom, and an oxygen atom.

4. The polishing composition according to claim 3, wherein the biocide is at least one selected from the group consisting of compounds represented by chemical formulas 1-a to 1-c below: 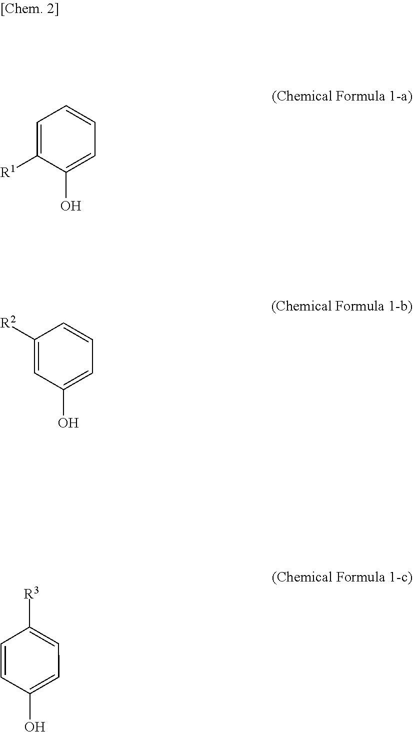
wherein, in chemical formula 1 above, R¹ to R³ each independently represent a substituent including at least two atoms selected from the group consisting of a carbon atom, a hydrogen atom, and an oxygen atom.

5. The polishing composition according to claim 3, wherein the biocide is at least one selected from the group consisting of ethyl paraoxybenzoate, butyl paraoxybenzoate, and phenylphenol.

6. The polishing composition according to claim 1, wherein the biocide is an unsaturated fatty acid.

7. The polishing composition according to claim 6, wherein the unsaturated fatty acid is sorbic acid.

8. The polishing composition according to claim 1, wherein the polishing speed adjusting agent for an object to be polished containing a silicon material having the silicon-silicon bonding is at least one selected from the group consisting of a water-soluble polymer having a polyalkylene chain and a surfactant having a polyoxyalkylene chain.

9. The polishing composition according to claim 8, wherein the water-soluble polymer having a polyalkylene chain is at least one selected from the group consisting of a polyalkylene glycol and a polyalkylene copolymer.

10. The polishing composition according to claim 9, wherein the polyalkylene glycol is at least one of polypropylene glycol and polybutylene glycol.

11. The polishing composition according to claim 1, wherein the polishing composition has a pH of higher than 3.5.

12. The polishing composition according to claim 1, further comprising a dissolution aid for the biocide.

13. A polishing method comprising polishing an object to be polished containing a silicon material having silicon-silicon bonding by using the polishing composition according to claim 1.
